(19) United States
(12) Patent Application Publication
(10) Pub. No.: US 2012/0090546 A1
(43) Pub. Date: Apr. 19, 2012

(54) SOURCE SUPPLYING UNIT, METHOD FOR SUPPLYING SOURCE, AND THIN FILM DEPOSITING APPARATUS

(75) Inventors: Kyung Bin Bae, Gyeonggi-Do (KR); Jun Seo Rho, Seoul (KR); Whang Sin Cho, Seoul (KR); Jin Haon Kwon, Chungcheongnam-Do (KR); Jong Ha Lee, Gyeonggi-Do (KR); You Hyun Kim, Incheon (KR); Hyung Seok Yoon, Gyeonggi-Do (KR)

(73) Assignee: SNU PRECISION CO., LTD, Seoul (KR)

(21) Appl. No.: 13/260,271

(22) PCT Filed: Mar. 26, 2009
(86) PCT No.: PCT/KR2010/001849

§ 371 Date: Dec. 14, 2011

(30) Foreign Application Priority Data
Mar. 26, 2009 (KR) 10-2009-0025893

(51) Int. Cl. C23C 16/448; H05B 1/00

(52) U.S. Cl. 118/724; 219/201; 118/726

(57) ABSTRACT

Provided are a source supplying unit and a method for supplying a source. The source supplying unit includes a pot configured to store a source material, an injector communicating with the pot to inject the source material evaporated from the pot, a high frequency coil part surrounding an outside of the pot, and a resistance-type heating part disposed at an outside of the injector. Since a high frequency induction heating method and a resistance-type heating method are combined to evaporate a source material to be supplied, a large amount of source material can be used, and the thickness and quality of a thin film can be easily controlled.

### TECHNICAL FIELD

The present disclosure relates to a source supplying unit, and more particularly, to a source supplying unit configured to evaporate a source material and supply the source material, a method for supplying a source, and a thin film depositing apparatus.

### BACKGROUND ART

Solar cells are semiconductor devices that use photovoltaic effect to convert light energy into electrical energy, and are recently receiving increased attention due to the depletion of fossil fuels. Specifically, compound thin film solar cells such as copper indium gallium selenide (CIGS) thin film solar cells or cadmium telluride (CdTe) solar cells are manufactured through relatively simple manufacturing processes, and manufacturing costs thereof are low. In addition, such a compound thin film solar cell has the same light conversion efficiency as those of other related art solar cells. Thus, compound thin film solar cells are being regarded with much interest as the next generation solar cells.

Since organic light emitting devices (OLEDs) are self-luminescent devices unlike liquid crystal display devices, they do not require a backlight, and thus, their power consumption is low. Furthermore, since OLEDs have wide viewing angles and high response speeds, a display device including OLEDs displays an improved image having a wide viewing angle without a residual image.

Meanwhile, inorganic thin films and metal thin films used in manufacturing solar cells and organic light emitting devices may be used as light absorption/transmission layers and electrodes of solar cells, or used as electron injection layers (EILs) or cathodes of organic light emitting devices. Such inorganic thin films and metal thin films may be manufactured through a process such as a resistance heating-type vacuum deposition method, a sputtering method, a chemical vapor deposition (CVD) method, and a high frequency induction heating method. Typically, such processes may be selectively used to form inorganic thin films and metal thin films.

However, since the resistance heating-type vacuum deposition method that is a related art method has a limited input capacity in a source material, productivity is low. In addition, since a process direction is limited to an upward type, as a substrate increases in area, the hanging down of the substrate also increases. In addition, since the sputtering method has great collision energy, when manufacturing an organic light emitting device, an organic thin film of a lower layer is damaged to degrade device characteristics. In addition, since simultaneous deposition of various materials is difficult when manufacturing a solar cell device such as a compound thin film solar cell, characteristic improvement of a solar cell device using combination deposition of various materials is difficult. In addition, high frequency induction heating method uses a large amount of source material to improve productivity, but evaporation density of a source material is uneven, and evaporation quality is low, so that control of the thickness and quality of a thin film is difficult.

### DISCLOSURE OF INVENTION

### Technical Problem

The present disclosure provides a source supplying unit, a method for supplying a source, and a thin film depositing apparatus, which can use a large amount of source material and facilitate control of the thickness and quality of a thin film.

The present disclosure also provides a source supplying unit, a method for supplying a source, and a thin film depositing apparatus, which can prevent hanging down of a wide substrate since a deposition direction through the source supplying unit is not limited to a specific direction.

### Solution to Problem

In accordance with an exemplary embodiment, a source supplying unit includes: a pot configured to store a source material; an injector communicating with the pot to inject the source material evaporated from the pot; a high frequency coil part surrounding an outside of the pot; and a resistance-type heating part disposed at an outside of the injector.

The high frequency coil part may include: a conductor pipe having a coil shape surrounding the outside of the pot; and a cooling medium circulating in the conductor pipe.

The conductor pipe may be formed of copper.

The injector may include: a communication passage disposed in a body of the injector such that the source material evaporated from the pot flows; and a plurality of injection holes connected to the communication passage and open out of the body.

The injection hole may have an injection nozzle shape protruding a predetermined length.

The resistance-type heating part may surround at least one of an entire outside region of the injector.

A cooling member may be disposed at an outside of the resistance-type heating part.

The cooling member may surround at least one of an entire outside region of the injector.

In accordance with another exemplary embodiment, a method for supplying a source includes: filling a pot with a source material; evaporating the source material through high frequency induction heating; and further evaporating the source material, flowing through an injector connected to the pot, through resistance-type heating.

The method may further include injecting the source material, evaporated through the resistance-type heating, in a line or plane shape onto a substrate.

The high frequency induction heating and the resistance-type heating may include cooling an outer space through which the source material is supplied.

In accordance with another exemplary embodiment, a thin film depositing apparatus includes: a chamber; a substrate support part disposed in the chamber to support a substrate; and a source supplying unit facing the substrate to supply a source material to the substrate, wherein the source supplying unit includes: a first evaporation part configured to primarily evaporate the source material through high frequency induction heating; and a second evaporation part configured to secondly evaporate the source material, evaporated through the first evaporation part, through resistance-type heating.

The first evaporation part may include: a pot configured to store the source material; and a high frequency coil part surrounding an outside of the pot.

The high frequency coil part may include: a conductor pipe having a coil shape surrounding the outside of the pot; and a cooling medium circulating in the conductor pipe.

The second evaporation part may include: an injector configured to inject the evaporated source material; and a resistance-type heating part disposed at an outside of the injector.

A cooling member may be disposed at an outside of the resistance-type heating part.

### ADVANTAGEOUS EFFECTS OF INVENTION

In accordance with the present disclosure, since a high frequency induction heating method and a resistance-type heating method are combined to evaporate a source material to be supplied, a large amount of source material can be used, and the thickness and quality of a thin film can be easily controlled.

In addition, since a deposition direction through the source supplying unit is not limited to a specific direction, an optimized direction is selected according to the area of a substrate, in performing the process. Thus, even when a substrate having a large area is used, a downward deposition direction is selected to prevent hanging down of a substrate, thus forming a high quality thin film on a substrate.

### BRIEF DESCRIPTION OF DRAWINGS

Exemplary embodiments can be understood in more detail from the following description taken in conjunction with the accompanying drawings, in which:

FIG. 1 is a schematic view of a thin film depositing apparatus including a source supplying unit in accordance with an exemplary embodiment;

FIG. 2 is a perspective view of a source supplying unit in accordance with an exemplary embodiment;

FIG. 3 is a cross-sectional view taken along a Y-axis of the source supplying unit of FIG. 2;

FIG. 4 is a cross-sectional view taken along an X-axis of the source supplying unit of FIG. 2; and

FIGS. 5 and 6 are schematic views illustrating process directions of a source supplying unit in accordance with an exemplary embodiment.

### BEST MODE FOR CARRYING OUT THE INVENTION

Hereinafter, specific embodiments will be described in detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Like reference numerals refer to like elements throughout.

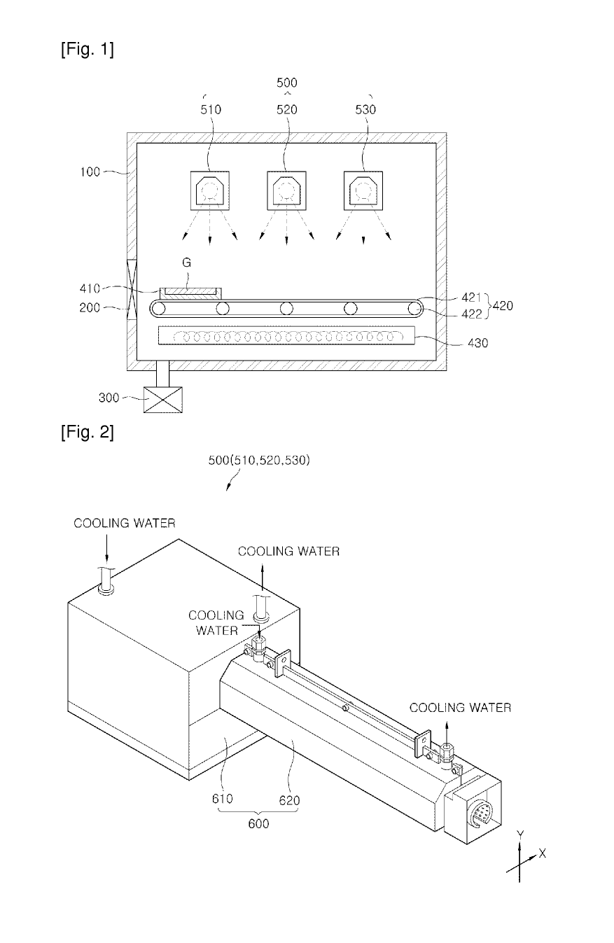

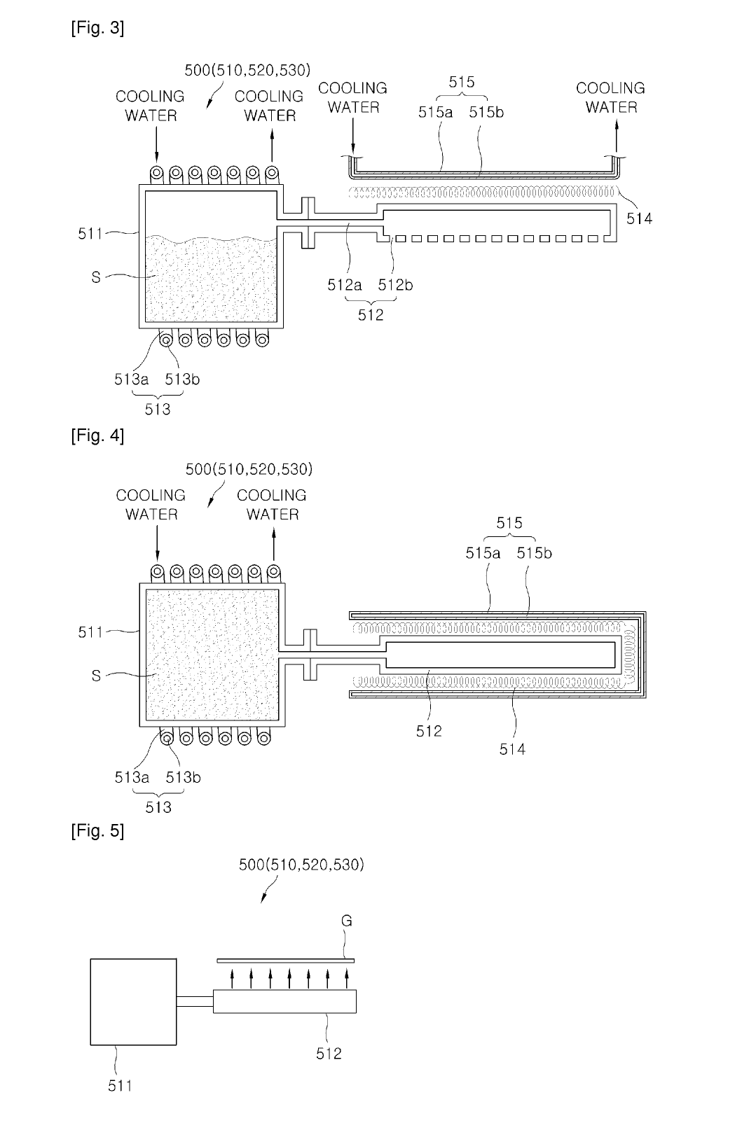

FIG. 1 is a schematic view of a thin film depositing apparatus including a source supplying unit in accordance with an exemplary embodiment. FIG. 2 is a perspective view of a source supplying unit in accordance with an exemplary embodiment. FIG. 3 is a cross-sectional view taken along a Y-axis of the source supplying unit of FIG. 2. FIG. 4 is a cross-sectional view taken along an X-axis of the source supplying unit of FIG. 2. In FIGS. 3 and 4, a housing is removed from the source supplying unit of FIG. 2

Referring to FIGS. 1 through 4, the thin film depositing apparatus includes a chamber 100, a substrate support part 410 disposed in the chamber 100 to support a substrate G, a source supplying unit 500 facing the substrate G to supply a source material to the substrate G, and a substrate movement member 420 for a relative movement between the substrate support part 410 and the source supplying unit 500. Further, the thin film depositing apparatus may include a substrate heating member 430 heating the substrate G supported on the substrate support part 410 to a predetermined temperature.

The chamber 100 has a hollowed cylindrical shape or a tetragonal box shape, and provides a predetermined reaction space for processing the substrate G. However, the shape of the chamber 100 is not limited thereto, and thus, the chamber 100 may have any shape corresponding the shape of the substrate G. For example, in the current embodiment, the chamber 100 has a tetragonal box shape for corresponding to a tetragonal glass substrate as the substrate G. A side wall of the chamber 100 is provided with a gate 200 for loading and unloading the substrate G, and a lower wall of the chamber 100 is provided with an exhaust part 300 for vacuum formation and inside exhaust. The gate 200 may be configured by a slit valve, and the exhaust part 300 may be configured by a vacuum pump. Although the chamber 100 is exemplified as a single body, the chamber 100 may include a discrete lower chamber having an open upper portion, and a discrete chamber lid covering the upper portion of the lower chamber.

The substrate support part 410 is disposed at the lower space in the chamber 100, and supports the substrate G loaded in the chamber 100. A surface of the substrate support part 410 on which the substrate G is placed, that is, the upper surface of the substrate support part 410 is provided with a member for fixing the placed substrate G, for example, provided with one of various chuck members that use force such as mechanical force, vacuum suction force, and electrostatic force to hold the substrate G, or may be provided with a holder member such as a clamp. Although not shown, a shadow mask may be disposed at the upper portion of the substrate support part 410 such that a thin film is prevented from being formed at the edge of the substrate G or a thin film formed on a substrate has a predetermined pattern. As a matter of course, the shadow mask may be installed independently from the substrate support part 410 such that the shadow mask is supported by an inner side wall of the chamber 100.

The substrate movement member 420 is disposed at the lower side of the substrate support part 410 to vertically and horizontally transfer and rotate the substrate support part 410. For example, the substrate movement member 420 includes a conveyor belt 421 and a driving wheel 422 controlling left and right movement of the conveyor belt 421 to reciprocate, along the left and right direction, the substrate support part 410 supported by the upper surface of the conveyor belt 421. The single substrate support part 410 is disposed in the chamber 100, but the present disclosure is not limited thereto. Thus, a plurality of substrate support parts may be disposed in the chamber 100. Furthermore, the single substrate G is disposed in the substrate support part 410, but the present disclosure is not limited thereto. Thus, a plurality of substrates may be disposed in the substrate support part 410.

The substrate heating member 430 may be disposed at the lower side of the substrate movement member 420 to heat the substrate G, placed on the substrate support part 410, to a predetermined temperature. The substrate heating member 430 applies predetermined heat to the substrate G placed on the substrate support part 410 to improve reactivity with a deposition material deposited on the upper portion of the substrate G, and may be configured by one of various heating members such as a resistance heater and a lamp heater.

The source supplying unit 500 is disposed at the upper portion in the chamber 100 to face the substrate G supported by the substrate support part 410 and supply an evaporated source material to the substrate G. The source supplying unit 500 includes one or more source supplying units 510, 520, and 530, which may be spaced an identical distance from each other on an identical horizontal or vertical plane.

The source supplying units 510, 520, and 530 each includes a pot 511 storing a source material S, an injector 512 communicating with the pot 511 to inject the source material S evaporated at the pot 511, heating parts 513 and 514 heating the pot 511 and the injector 512 to a predetermined temperature, and a housing 600 enveloping the pot 511, the injector 512, and the heating parts 513 and 514. Specifically, the heating parts 513 and 514 include a high frequency coil part that is also denoted by reference numeral 513 and surrounds the outside of the pot 511, and a resistance-type heating part that is also denoted by reference numeral 514 and disposed at the outside of the injector 512. In this case, the pot 511 and the high frequency coil part 513 constitute a first evaporation part that uses high frequency induction heating to primarily heat a source material, and the injector 512 and the resistance-type heating part 514 constitute a second evaporation part that uses resistance-type heating to secondly heat the source material evaporated through the first evaporation part.

The pot 511 has a box shape or a cylinder shape with an open side, and is filled with the source material of a thin film to be deposited on the substrate G. In the current embodiment, for example, a powder type inorganic source fills the pot 511 to form an inorganic thin film on the substrate G. The injector 512 has a bar shape that horizontally extends a predetermined length from a side of the pot 511. The injector 512 may vertically or obliquely extend according to a process direction, and have a point-type injection structure or a plane-type injection structure instead of a line-type injection structure such as a bar shaped injection structure. A communication passage 512a to which the source material S evaporated at the pot 511 is introduced is disposed in a body of the injector 512. A plurality of injection holes 512b extending from the communication passage 512a and opened outward are disposed in the outer surface of the body of the injector 512. The positions and number of the injection holes 512b may be controlled to inject the source material S in a vapor state toward the substrate G. The injection holes 512b may have injection nozzle shapes protruding a predetermined length from the body of the injector 512 to the outside. Thus, the source material S evaporated at the pot 511 flows through the communication passage 512a of the injector 512, and is uniformly injected to the upper portion of the substrate G through the injection holes 512b of the injector 512.

The high frequency coil part 513 includes a conductor pipe 513a having a coil shape surrounding the outside of the pot 511, and a cooling medium 513b circulating in the conductor pipe 513a. The conductor pipe 513a may be a copper pipe having high conductivity, and the cooling medium 513b may be water. The cooling medium 513b circulates in the conductor pipe 513a to which high frequency waves are applied, to prevent overheating of the conductor pipe 513a, and simultaneously, to prevent heat emitted to the outside of the conductor pipe 513a from varying process conditions in the chamber 100.

The resistance-type heating part 514 surrounds at least one portion of an outside region of the injector 512, which is out of the injection holes 512b. The resistance-type heating part 514 further heats (secondary evaporation) the source material S evaporated at the pot 511 heated by the high frequency coil part 513 and flowing to the communication passage 512b of the injector 512. Accordingly, the evaporation state of the source material S flowing along the communication passage 512b can be maintained, and evaporation density and evaporation quality can be further improved. A cooling member 515 may be disposed at the outside of the resistance-type heating part 514 to prevent the resistance-type heating part 514 from varying process conditions in the chamber 100. For example, in the current embodiment, a cooling pipe 515a in which cooling water 515b circulates is disposed at the outside of the resistance-type heating part 514.

The housing 600 includes a first housing 610 accommodating the pot 511 and the high frequency coil part 513, and a second housing 620 accommodating the injector 512, the resistance-type heating part 514, and the cooling member 515. The second housing 620 has a lamp shade shape that is open at a side provided with the injection holes 512b of the injector 512, and thus, allows the evaporated and injected source material S to be supplied to a side where the substrate G is disposed.

Since the source supplying unit 500 configured as described above has the characteristics of a high frequency induction heating method that facilitates evaporation of a large amount of source, and the characteristics of a resistance-type heating method that facilitates quality control of evaporated source, a high quality thin film can be quickly and continuously formed without a process stop due to frequent source replacement.

An operation of the thin film depositing apparatus including the source supplying unit 500 will now be described with reference to FIGS. 1 through 4.

First, when the substrate G is loaded into the chamber 100, and placed on the substrate support part 410, the substrate heating member 430 is operated to heat the substrate G to a predetermined process temperature. Then, the substrate transfer member 420 reciprocates the substrate G along the left and right direction, and the source supplying units 510, 520, and 530 each injects the source material S in a vapor state to the upper surface of the substrate G. In each of the source supplying units 510, 520, and 530, the high frequency coil part 513 heats the pot 511 to a predetermined temperature, so that the source material S is primarily evaporated in the pot 511. The evaporated source material S flows along the communication passage 512a in the injector 512 connected to the pot 511. At this point, since the source material S flowing along the communication passage 512a is secondly evaporated by heat provided from the resistance-type heating part 514 disposed at the outside of the injector 512, evaporation density is more uniform, and evaporation quality is further improved. Thus, a source material is injected with uniform evaporation density and improved evaporation quality through the injection holes 512b of the injector 512, so as to form a high quality thin film having a uniform thickness on the substrate G.

As such, the source supplying unit 500 uses the high frequency induction heating method to primarily evaporate a source material of the pot 511, and uses the resistance-type heating method to secondly evaporate the source material evaporated at the pot 511 and flowing into the injector 512, and then, injects the source material onto the substrate G. Thus, the characteristic of the high frequency induction method, that is, quick evaporation of a large amount of source can be achieved to prevent a process stop due to frequent source replacement, and prevent process delay due to evaporation delay. In addition, since the characteristic of the resistance-type heating method, that is, uniform evaporation quality can be maintained, thickness adjustment of a thin film can be facilitated, and a high quality thin film can be formed.

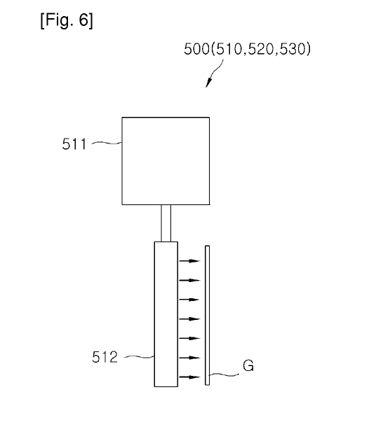

The source supplying unit 500 is configured in a downward manner that a source material is supplied to the upper portion of the substrate G. Thus, the entire lower surface of the substrate G can be stably supported by the upper surface of the substrate support part 410. Even when the substrate G has a large area, the substrate G substantially does not hang down. As a matter of course, since the position of the source supplying unit 500 is not limited in the present disclosure, the process direction is not limited to the downward manner. That is, referring to FIG. 5, the source supplying unit 500 may be configured in an upward manner that a source material is supplied at the lower side of the substrate G. In addition, referring to FIG. 6, the source supplying unit 500 may be configured in a lateral manner that a source material is supplied at a side surface of the substrate G that is vertically disposed. FIGS. 5 and 6 are schematic views illustrating process directions of a source supplying unit in accordance with an exemplary embodiment.

As described above, since the deposition direction of the thin film depositing apparatus including the source supplying unit 500 is not limited, a desired process direction can be freely selected according to the characteristics of a substrate.

Although the source supplying unit, the method for supplying a source, and the thin film depositing apparatus have been described with reference to the specific embodiments, they are not limited thereto. Therefore, it will be readily understood by those skilled in the art that various modifications and changes can be made thereto without departing from the spirit and scope of the present invention defined by the appended claims.

1. A source supplying unit comprising:
a pot configured to store a source material;
an injector communicating with the pot to inject the source material evaporated from the pot;
a high frequency coil part surrounding an outside of the pot; and
a resistance-type heating part disposed at an outside of the injector.

2. The source supplying unit of claim 1, wherein the high frequency coil part comprises:
a conductor pipe having a coil shape surrounding the outside of the pot; and
a cooling medium circulating in the conductor pipe.

3. The source supplying unit of claim 2, wherein the conductor pipe is formed of copper.

4. The source supplying unit of claim 1, wherein the injector comprises:
a communication passage disposed in a body of the injector such that the source material evaporated from the pot flows; and
a plurality of injection holes connected to the communication passage and opens out of the body.

5. The source supplying unit of claim 1, wherein the injector comprises:
a communication passage disposed in a body of the injector such that the source material evaporated from the pot flows; and
a plurality of injection holes connected to the communication passage and opens out of the body,
wherein the injection hole has an injection nozzle shape protruding a predetermined length.

6. The source supplying unit of claim 1, wherein the resistance-type heating part surrounds at least one of an entire outside region of the injector.

7. The source supplying unit of claim 1, wherein a cooling member is disposed at an outside of the resistance-type heating part.

8. The source supplying unit of claim 7, wherein the cooling member surrounds at least one of an entire outside region of the injector.

9. A method for supplying a source, the method comprising:
filling a pot with a source material;
evaporating the source material through high frequency induction heating; and
further evaporating the source material, which flows through an injector connected to the pot, through resistance-type heating.

10. The method of claim 9, further comprising injecting the source material, which is evaporated through the resistance-type heating, in a line or plane shape onto a substrate.

11. The method of claim 9, wherein the high frequency induction heating and the resistance-type heating comprise cooling an outer space through which the source material is supplied.

12. A thin film depositing apparatus comprising:
a chamber;
a substrate support part disposed in the chamber to support a substrate; and
a source supplying unit facing the substrate to supply a source material to the substrate,
wherein the source supplying unit comprises:
a first evaporation part configured to primarily evaporate the source material through high frequency induction heating; and
a second evaporation part configured to secondly evaporate the source material, which is evaporated through the first evaporation part, through resistance-type heating.

13. The thin film depositing apparatus of claim 12, wherein the first evaporation part comprises:
a pot configured to store the source material; and
a high frequency coil part surrounding an outside of the pot.

14. The thin film depositing apparatus of claim 13, wherein the high frequency coil part comprises:
a conductor pipe having a coil shape surrounding the outside of the pot; and
a cooling medium circulating in the conductor pipe.

15. The thin film depositing apparatus of claim 12, wherein the second evaporation part comprises:
an injector configured to inject the evaporated source material; and
a resistance-type heating part disposed at an outside of the injector.

16. The thin film depositing apparatus of claim 15, wherein a cooling member is disposed at an outside of the resistance-type heating part.
